(19) United States
(12) Patent Application Publication
(10) Pub. No.: US 2014/0266059 A1
(43) Pub. Date: Sep. 18, 2014

(54) SELECTIVE UPDATING OF BATTERY PARAMETER ESTIMATIONS

(71) Applicant: FORD GLOBAL TECHNOLOGIES, LLC, Dearborn, MI (US)

(72) Inventors: YONGHUA LI, Ann Arbor, MI (US); XU WANG, Dearborn, MI (US)

(73) Assignee: FORD GLOBAL TECHNOLOGIES, LLC, Dearborn, MI (US)

(21) Appl. No.: 13/829,391

(22) Filed: Mar. 14, 2013

(51) Int. Cl. G01R 31/36

(52) U.S. Cl. CPC G01R 31/3624
USPC 320/132

(57) ABSTRACT

A vehicle is provided with an electric machine that is configured to provide drive torque, and a battery for supplying power to the electric machine. The vehicle also includes a controller that is configured to estimate present battery parameters based on input indicative of the power supplied by the battery. The controller is also configured to generate output indicative of battery power capability based on the input and prior battery parameters in response to a rate of change of a component of the power being less than a lower boundary.

### TECHNICAL FIELD

One or more embodiments relate to a vehicle system for selectively updating battery parameter estimations.

### BACKGROUND

In vehicles having a traction battery system, such as a hybrid electric vehicle (HEV), plug-in HEV (PHEV) or battery electric vehicle (BEV), vehicle controls evaluate a level of charge in the battery (state of charge (SOC)), and how much power the battery is capable of providing (discharge) or receiving (charge) in order to meet the driver demand and to optimize the energy usage (power limit). A battery may be represented by an equivalent circuit model (ECM) having battery ECM parameters (circuit elements) that represent battery characteristics. SOC and power capability may be calculated based on the battery ECM parameters.

A battery management system may also calculate the SOC as a percentage of available charge as compared with a maximum charge capacity. One such method for calculating SOC is the ampere-hour integration method. A battery management system may, for example, calculate the battery power limit based on battery age, temperature, and SOC. The SOC and the battery power limits can then be provided to various other vehicle controls, for example, through a vehicle system controller (VSC) so that the information can be used by systems that may draw power from or provide power to the traction battery.

### SUMMARY

In one embodiment, a vehicle is provided with an electric machine that is configured to provide drive torque, and a battery for supplying power to the electric machine. The vehicle also includes a controller that is configured to estimate present battery parameters based on input indicative of the power supplied by the battery. The controller is also configured to generate output indicative of battery power capability based on the input and prior battery parameters in response to a rate of change of a component of the power being less than a lower boundary.

In another embodiment, a vehicle system is provided with a battery for supplying power and a controller. The controller is configured to receive a first input indicative of first battery power, and to receive a second input indicative of second battery power. The controller is further configured to generate output indicative of battery power capability based on the second input and prior battery parameters based on the first input in response to a rate of change of a component of the second input being less than a lower boundary.

In yet another embodiment, a method is provided for controlling a hybrid vehicle. A first input is received, that is indicative of first battery power. A second input is received, that is indicative of second battery power. Battery power capability is calculated based on the second input and an estimate of first battery ECM parameters based on the first input in response to a rate of change of a component of the second input being less than a lower boundary.

As such, the vehicle, vehicle system and method provide advantages over existing methods by bypassing presently estimated EKF estimations, and referencing prior ECM parameters, when the signal characteristics of the input are, for example, low or stationary, and thus insufficient for EKF estimations. Such selective updating of battery ECM parameters results in a more accurate estimation of battery characteristics (e.g., power capability and SOC) throughout the battery operating range and at different vehicle conditions.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompanying drawings in which:

FIG. 1 is a schematic diagram of a vehicle, illustrated with a vehicle system for selectively updating battery ECM parameters according to one or more embodiments;

FIG. 2 is a general circuit model that can be used by the vehicle system of FIG. 1 to model the behavior of a battery;

FIG. 3 is a detailed circuit model based on the general circuit model of FIG. 2;

FIG. 4 is a graph illustrating a battery ECM parameter estimated in accordance with one or more embodiments;

FIG. 4A is an enlarged view of a portion of FIG. 4; and

FIG. 5 is a flow chart illustrating a method for selectively updating battery ECM parameters according to one or more embodiments.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

With reference to FIG. 1, a vehicle system for selectively updating battery ECM parameters is illustrated in accordance with one or more embodiments and is generally referenced by numeral 10. The vehicle system 10 is depicted within a vehicle 12. The vehicle system 10 includes a controller, such as a battery control module (BECM) 14 and a battery 16 that are in communication with each other. The BECM 14 receives input including battery temperature, voltage and current; and estimates battery ECM parameters based on the input. The BECM 14 may also calculate battery power capability (P_{cap}) and battery SOC based on the input and the battery ECM parameters. The vehicle system 10 is configured to selectively update the battery ECM parameters based on the signal characteristics of the input.

The illustrated embodiment depicts the vehicle 12 as an HEV, which is an electric vehicle propelled by an electric machine 18 with assistance from an internal combustion engine 20. The electric machine 18 is an AC electric motor according to one or more embodiments, and is depicted as a “motor” 18 in FIG. 1. The electric machine 18 receives electrical power and provides drive torque for vehicle propulsion. The electric machine 18 also functions as a generator for converting mechanical power into electrical power through regenerative braking.

The vehicle 12 includes a transmission 22 having a power-split configuration, according to one or more embodiments. The transmission 22 includes the first electric machine 18 and a second electric machine 24. The second electric machine 24 is an AC electric motor according to one or more embodiments, and is depicted as a “generator” 24 in FIG. 1. Like the first electric machine 18, the second electric machine 24 receives electrical power and provides output torque. The second electric machine 24 also functions as a generator for converting mechanical power into electrical power and optimizing power flow through the transmission 22.

The transmission 22 includes a planetary gear unit 26, which includes a sun gear 28, a planet carrier 30 and a ring gear 32. The sun gear 28 is connected to an output shaft of the second electric machine 24 for receiving generator torque. The planet carrier 30 is connected to an output shaft of the engine 20 for receiving engine torque. The planetary gear unit 26 combines the generator torque and the engine torque and provides a combined output torque about the ring gear 32. The planetary gear unit 26 functions as a continuously variable transmission, without any fixed or “step” ratios.

The transmission 22 also includes a one-way clutch (O.W.C.) and a generator brake 33, according to one or more embodiments. The O.W.C. is coupled to the output shaft of the engine 20 to only allow the output shaft to rotate in one direction. The O.W.C. prevents the transmission 22 from back-driving the engine 20. The generator brake 33 is coupled to the output shaft of the second electric machine 24. The generator brake 33 may be activated to “brake” or prevent rotation of the output shaft of the second electric machine 24 and of the sun gear 28. In other embodiments, the O.W.C. and the generator brake 33 are eliminated, and replaced by control strategies for the engine 20 and the second electric machine 24.

The transmission 22 includes a countershaft having a first gear 34, a second gear 36 and a third gear 38. A planetary output gear 40 is connected to the ring gear 32. The planetary output gear 40 meshes with the first gear 34 for transferring torque between the planetary gear unit 26 and the countershaft. An output gear 42 is connected to an output shaft of the first electric machine 18. The output gear 42 meshes with the second gear 36 for transferring torque between the first electric machine 18 and the countershaft. A transmission output gear 44 is connected to a transmission output shaft 46. The transmission output shaft 46 is coupled to a pair of driven wheels 48 through a differential 50. The transmission output gear 44 meshes with the third gear 38 for transferring torque between the transmission 22 and the driven wheels 48.

Although illustrated and described in the context of a HEV 12, it is understood that embodiments of the present application may be implemented on other types of electric vehicles, such as BEVs which are powered by an electric motor without assistance of an internal combustion engine.

The vehicle 12 includes the battery 16 for storing electrical energy. The battery 16 is a high voltage battery that is capable of outputting electrical power to operate the first electric machine 18 and the second electric machine 24. The battery 16 also receives electrical power from the first electric machine 18 and the second electric machine 24 when they are operating as generators. The battery 16 is a battery pack made up of several battery modules (not shown), where each battery module contains a plurality of battery cells (not shown). Other embodiments of the vehicle 12 contemplate different types of energy storage systems, such as capacitors and fuel cells (not shown) that supplement or replace the battery 16. A high voltage bus electrically connects the battery 16 to the first electric machine 18 and to the second electric machine 24.

The BECM 14 controls the battery 16. The BECM 14 receives input that is indicative of vehicle conditions and battery conditions, such as battery temperature, voltage and current. The BECM 14 estimates battery ECM parameters that correspond to battery characteristics based on the input. The BECM 14 also calculates the SOC and the battery power capability (P_{cap}) based on the input and the battery ECM parameters. The BECM 14 provides output (SOC, P_{cap}) that is indicative of the SOC and the battery power capability to other vehicle systems and controllers. In another embodiment, the BECM 14 receives the battery SOC as an input.

The vehicle 12 includes a variable voltage converter (VVC) 52 and an inverter 54 that are electrically connected along the high voltage bus. The VVC 52 boosts or steps up the voltage potential of the electrical energy that is provided by the battery 16. The VVC 52 may also “buck” or step down the voltage potential of the electrical energy that is provided to the battery 16, according to one or more embodiments. The inverter 54 inverts the direct current (DC) energy supplied by the battery 16 (through the VVC 52) to alternating current (AC) energy for operating the electric machines 18, 24. The inverter 54 also rectifies AC power provided by the electric machines 18, 24, to DC for charging the main battery 16.

The transmission 22 includes a transmission control module (TCM) 58 for controlling the electric machines 18, 24, the VVC 52 and the inverter 54. The TCM 58 is configured to monitor, among other things, the position, speed, and power consumption of the electric machines 18, 24. The TCM 58 also monitors electrical parameters (e.g., voltage and current) at various locations within the VVC 52 and the inverter 54, according to one or more embodiments. The TCM 58 provides output signals corresponding to this information to other vehicle systems.

The vehicle 12 includes a vehicle system controller (VSC) 60 that communicates with other vehicle systems and controllers for coordinating their function. Although it is shown as a single controller, the VSC 60 may include multiple controllers that may be used to control multiple vehicle systems according to an overall vehicle control logic, or software.

The vehicle controllers, including the VSC 60 and the BECM 14 generally include any number of microprocessors, ASICs, ICs, memory (e.g., FLASH, ROM, RAM, EPROM and/or EEPROM) and software code to co-act with one another to perform a series of operations. The controllers also include predetermined data, or “look up tables” that are based on calculations and test data and stored within the memory. The VSC 60 communicates with other vehicle systems and controllers (e.g., the BECM 14 and the TCM 58) over one or more hardwired or wireless vehicle connections using common bus protocols (e.g., CAN and LIN). The VSC 60 receives input (PRND) that represents a current position of the transmission 22 (e.g., park, reverse, neutral or drive). The VSC 60 also receives input (APP) that represents an accelerator pedal position. The VSC 60 provides output that represents a desired wheel torque, desired engine speed, and generator brake command to the TCM 58; and contactor control to the BECM 14.

The vehicle 12 includes a braking system (not shown) which includes a brake pedal, a booster, a master cylinder, as well as mechanical connections to the driven wheels 48, to effect friction braking. The braking system also includes position sensors, pressure sensors, or some combination thereof for providing information such as brake pedal position (BPP) that corresponds to a driver request for brake torque. The braking system also includes a brake system control module (BSCM) 62 that communicates with the VSC 60 to coordinate regenerative braking and friction braking. The BSCM 62 provides a regenerative braking command to the VSC 60, according to one embodiment.

The vehicle 12 includes an engine control module 64 for controlling the engine 20. The VSC 60 provides output (desired engine torque) to the engine control module 64 that is based on a number of input signals including APP, and corresponds to a driver's request for vehicle propulsion.

The vehicle 12 is configured to receive power from an external source, according to one or more embodiments. The battery 16 periodically receives AC energy from an external power supply or grid, via a charge port 66. The charge port 66 may be configured to receive an external electrical plug or connector (“plug-in”), or may be configured for inductive charging. The vehicle 12 also includes an on-board charger 68, which receives the AC energy from the charge port 66. The charger 68 is an AC/DC converter which converts the received AC energy into DC energy suitable for charging the battery 16. In turn, the charger 68 supplies the DC energy to the battery 16 during recharging.

Referring to FIGS. 1 and 2, the BECM 14 is configured to receive input that is indicative of vehicle conditions and battery conditions, such as battery temperature, voltage and current. The BECM 14 estimates the battery ECM parameters based on the input. The BECM 14 also calculates the battery SOC and the battery power capability (P_{cap}) based on the battery ECM parameters and the input. The BECM 14 provides the P_{cap} and SOC to other vehicle systems and controllers that provide power to or receive power from the battery 16. For example, the TCM 58 may limit the amount of electrical power supplied to the electric machines 18, 24 when the SOC is below a low SOC threshold. The TCM 58 may also reduce the amount of electrical power supplied to the battery 16 from the electric machines 18, 24, when the SOC is above a high SOC threshold. In one or more embodiments, the BECM 14 receives the SOC as an input, and estimates P_{cap} based in part on the SOC.

FIG. 2 depicts a generalized equivalent circuit model 210 which represents the battery 16 and its internal impedance (Z). The battery load can be electrical components (e.g., the electric machines 18, 24) that are drawing current from the battery 16. Specified in the circuit model 210 are an open circuit voltage (V_{oc}), a battery current (I), a terminal voltage (Vₜ), and a generalized impedance sub-circuit (Z). It is understood that the sub-circuit (Z) may contain a number of different electrical elements, such as resistors, capacitors, inductors and the like. As discussed in detail below, the purpose of the circuit 210 is to provide information regarding a battery that can be used to determine SOC and P_{cap}. Therefore, the circuit model 210 may more accurately represent the behavior of the battery if the sub-circuit (Z) contains a relatively large number of electrical components. However, with an increased number of components in the sub-circuit (Z) there is also an increase in the complexity of the equations that govern the circuit model. As described above with respect to FIG. 1, the battery 16 is a battery pack made up of several battery modules (not shown), where each battery module contains a plurality of battery cells (not shown). The ECM 210 represents a battery pack, and the vehicle system 10 estimates battery parameters corresponding to the overall battery pack. However, other embodiments of the vehicle system 10 contemplate a battery cell equivalent circuit model for estimating battery cell parameters.

FIG. 3 illustrates a simplified Randle's equivalent circuit model 310 that is based on the general circuit model 210 of FIG. 2. The sub-circuit (Z) is made up of three discrete electrical components, specifically, two resistors (r₁, r₂) and one capacitor (c). A pair of governing equations for the circuit model 310 can be written as follows:

$$\begin{matrix}{\dot{V}}_{2} = - \frac{1}{{r}_{2} c} {V}_{2} + \frac{1}{c} I & Eq . 1 \\ {V}_{oc} - {V}_{t} = {V}_{2} + {Ir}_{1} & Eq . 2\end{matrix}$$

where: V₂ is a voltage across c or r₂ from the circuit model;

$${\dot{V}}_{2} = \frac{d {V}_{2}}{d t}$$

is the time based derivative of V₂; r₂ is a charge transfer resistance of the battery; c is a double layer capacitance of the battery; I is the measured battery current; V_{oc} is the open circuit voltage of the battery; Vₜ is the measured battery voltage across the battery terminals (terminal voltage); and r₁ is an internal resistance of the battery.

The battery current (I) and terminal voltage (Vₜ) may be regularly measured at some predetermined frequency so that these values can be used by other vehicle control systems. In the case of an open circuit voltage for the battery (V_{oc}) the value can be directly measured when the vehicle is started before an electrical contactor (not shown) is closed, if a battery internal diffusion process is considered to have stopped. When the vehicle is running, however, and the contactor is closed, the open circuit voltage (V_{oc}) is estimated. Additionally, the battery ECM parameters (r₁, r₂, and c) are estimated values.

There may be a number of ways to determine the V_{oc} from the SOC; the method that is used may depend, for example, on whether the SOC is known for the battery pack as a whole, or if the SOC is known for each of the individual battery cells. In the case where the SOC is known for each of the battery cells, Equation 3 as shown below can be used for battery pack V_{oc} determination.

V_{oc}=Σᵢ₌₁^{N}V_{oc}_{_{—}}_{cell i}=Σᵢ₌₁^{N}f(SOCᵢ) Eq. 3

where: N is the number of battery cells in the battery pack, and there is a one to one relationship between cell V_{oc} and cell SOC.

Using the known SOC values for each battery cell, a corresponding V_{oc} value can be determined from predetermined data, such as a lookup table or from some other known relationship between the V_{oc} and the SOC. Then, each of the calculated V_{oc}_{_{—}}_{cell} values for the individual battery cells can be summed to provide the total V_{oc} for the battery pack. In this model, it is assumed that the battery cells are connected in series, thereby making their voltages additive. Calculating the V_{oc} in this matter provides a very accurate estimate of the battery V_{oc}, which cannot be directly measured after the contactor is closed. By adding all of the V_{oc}_{_{—}}_{cell} values together, the weakest battery cells will lower the overall V_{oc} for the battery pack, ensuring that its value is not unrealistically high.

Another way to determine a V_{oc} for the battery pack is shown in Equations 4 and 5 below.

V_{oc}=N×V_{oc}_{_{—}}ₘᵢₙ=N×f(SOCₘᵢₙ)during discharge Eq. 4

V_{oc}=N×V_{oc}_{_{—}}ₘₐₓ=N×f(SOCₘₐₓ)during charge Eq. 5

where SOCₘᵢₙ refers to the minimum SOC among all cells in a series connection, while SOCₘₐₓ refers to the maximum SOC among all cells in a series connection.

As shown in Equations 4 and 5, the open circuit voltage (V_{oc}) is calculated using different equations, depending on whether the battery is presently discharging (Eq. 4), or charging (Eq. 5). The reason for this is that there are two different battery power capabilities, one associated with battery discharge and another associated with battery charge. Each of these battery power capabilities are limited by different values of the V_{oc}. For example, the discharge battery power capability is limited by the minimum V_{oc} for the battery pack; whereas, the charge battery power capability is limited by the maximum V_{oc} for the battery pack. Equations 4 and 5 can be used as an alternative to Equation 3 even if the SOC for each of the batteries cells is known. In such a case, the smallest battery cell SOC will be used in Equation 4, and the largest battery cell SOC used in Equation 5.

Although some of the variables occurring in Equations 1 and 2 such as (I) and (Vₜ) can be measured directly, the determination of other variables may require different approaches. For example, one way to determine values for at least some of the variables in Equations 1 and 2 is to apply a recursive parameter estimation method, such as a Kalman filter or an EKF to the equations. A Kalman filter is used for estimating states for a linear system. An EKF may be used for nonlinear systems, by utilizing a linearization process at every time step, to approximate the nonlinear system with a linear time varying system. Since battery parameter estimations are generally non-linear, the vehicle system estimates the battery ECM parameters using an EKF, according to one or more embodiments. One way that an EKF can be applied is to consider the current (I) as the input, the voltage (V₂) as a state, and the term (V_{oc}−Vₜ) as the output. The battery ECM parameters (r₁, r₂ and c) or their various combinations are also treated as states to be identified. Once the battery ECM parameters and other unknowns are identified, the SOC and the power capability can be calculated based on operating limits of a battery voltage and current, and the current battery state.

An EKF is a dynamic system, that is governed by the following equations:

Xₖ=f(Xₖ₋₁,uₖ₋₁,wₖ₋₁)

Yₖ=h(Xₖ,vₖ₋₁) Eq. 6

where: Xₖ includes the state V₂ and the other three battery ECM Parameters; uₖ is the input (e.g., battery current); wₖ is the process noise; Yₖ is the output (V_{oc}−Vₜ); and vₖ is the measurement noise.

One such system of equations for the battery model as considered can be shown as follows:

$$X = [ \begin{matrix}{X}_{1} \\ {X}_{2} \\ {X}_{3} \\ {X}_{4}\end{matrix} ] = [ \begin{matrix}{V}_{2} \\ \frac{1}{{r}_{2} c} \\ \frac{1}{c} \\ {r}_{1}\end{matrix} ]$$

The corresponding state space equation, in discrete or continuous time, can be obtained in the form of Equation 6.

Based on the system model shown in Equations 6, an observer is designed to estimate the extended states (x₁, x₂, x₃ and x₄), and correspondingly (V₂, r₁, r₂, and c), according to Equations 7-10 as shown below:

$$\begin{matrix}( {\hat{V}}_{2} ) = {x}_{1} & Eq . 7 \\ ( {\hat{r}}_{1} ) = {x}_{4} & Eq . 8 \\ ( {\hat{r}}_{2} ) = \frac{{x}_{3}}{{x}_{2}} & Eq . 9 \\ ( \hat{c} ) = \frac{1}{{x}_{3}} & Eq . 10\end{matrix}$$

The complete set of EKF equations consists of time update equations and measurement update equations. The EKF time update equations project the state and covariance estimate from the previous time step to the current step:

\hat{x}ₖ⁻=f(\hat{x}ₖ₋₁,uₖ₋₁,0)

Pₖ⁻=AₖPₖ₋₁Aₖ^{T}+WₖQₖ₋₁wₖ^{T} Eq. 11

where: \hat{x}ₖ⁻ represents a priori estimate of xₖ; Pₖ⁻ represents a priori estimate error covariance matrix; Aₖ represents the Jacobian matrix of the partial derivatives of f with respect to X; Pₖ₋₁ represents a posteriori estimate error matrix of last step; Aₖ^{T} represents transpose of matrix Aₖ; Wₖ represents the Jacobian matrix of the partial derivatives of f with respect to process noise variable w; Qₖ₋₁ represents a process noise covariance matrix, and Wₖ^{T} represents transpose of matrix Wₖ.

The measurement update equations correct the state and covariance estimate with the measurement:

Kₖ=Pₖ⁻Hₖ^{T}(HₖPₖ⁻Hₖ^{T}+VₖRₖVₖ^{T})⁻¹ Eq. 12

\hat{x}ₖ=\hat{x}ₖ⁻+Kₖ(zₖ−h)\hat{x}ₖ⁻,0)) Eq. 13

Pₖ=(1−KₖHₖ)Pₖ⁻ Eq. 14

where: Kₖ represents the EKF gain; Hₖ represents the Jacobian matrix of the partial derivatives of h with respect to X; Hₖ^{T} is the transpose of Hₖ; Rₖ represents a measurement noise covariance matrix; Vₖ represents the Jacobian matrix of the partial derivatives of h with respect to measurement noise variable v; and Vₖ^{T} is the transpose of Vₖ.

The first order differential equation from Equations 1 and 2 can be solved using the estimated battery ECM parameters of equations 7-10 to yield the following expression for the battery current (I).

$$I = \frac{( {V}_{oc} - {V}_{t} - {\hat{V}}_{2} ( 0 ) {e}^{- {t}_{d / ( {\hat{r}}_{2} * \hat{c} )}} )}{[ {\hat{r}}_{1} + {\hat{r}}_{2} ( 1 - {e}^{- {t}_{d} / ( {\hat{r}}_{2} * \hat{c} )} ) ]} \qquad Eq . 15$$

where: t_{d} is a predetermined time value; \hat{V}₂ (0) is the present value of V₂, and e is the base of the natural logarithm.

In general, once the value for (I) from Equation 15 is determined, the battery power capability can be found. Where it is desired to determine a charge power capability for the battery, Equation 15 can be solved for a minimum value of (I), such as shown in Equation 16. By convention, current is defined as a positive (+) quantity when flowing away from a battery (discharge), and as a negative (−) quantity when flowing into the battery (charge).

$${I}_{min} ( {t}_{d} , {V}_{max} ) = \frac{{V}_{oc} - {V}_{max} - {\hat{V}}_{2} ( 0 ) {e}^{- {t}_{d / ( {\hat{r}}_{2} \hat{c} )}}}{[ {\hat{r}}_{1} + {\hat{r}}_{2} ( 1 - {e}^{- {t}_{d} / ( {\hat{r}}_{2} \hat{c} )} ) ]} \leq 0 \qquad Eq . 16$$

where: the value of (t_{d}) is predetermined, and may be for example, between 1 sec. and 10 sec., and Vₘₐₓ is a maximum operating voltage for the battery, and may be considered a limiting battery voltage.

This current is then compared with a system charge current limit (Iₗᵢₘ_{_{—}}_{ch}). If Iₘᵢₙ(t_{d}, Vₘₐₓ)<Iₗᵢₘ_{_{—}}_{ch}, a second voltage value is calculated according to equation 17, as shown below:

$${\overline{V}}_{ch} = {V}_{oc} - {\hat{V}}_{2} ( 0 ) {e}^{- {t}_{d / ( {\hat{r}}_{2} \hat{c} )}} - {I}_{lim\_ch} * [ {\hat{r}}_{1} + {\hat{r}}_{2} ( 1 - {e}^{- {t}_{d} / ( {\hat{r}}_{2} \hat{c} )} ) ] \qquad Eq . 17$$

The time value (t_{d}) can be based on how battery power capabilities are used by vehicle system controller. The voltage (Vₘₐₓ) may be determined, for example, by a vehicle manufacturer or a battery manufacturer as the maximum voltage the battery is allowed to reach.

The charge power capability (P_{cap}_{_{—}}_{ch}(t_{d})) for a battery as a function of time (t_{d}) can be written in accordance with Equation 18.

$${P}_{cap\_ch} ( {t}_{d} ) = \{ \begin{matrix}\vert {I}_{min} \vert * {V}_{max} & if {I}_{min} \geq {I}_{lim\_ch} \\ \vert {I}_{lim\_ch} \vert * {\overline{V}}_{ch} & Otherwise\end{matrix} \qquad Eq . 18$$

In addition to determining a charge power capability for a battery, embodiments of the present invention also provide a method for determining a discharge power capability for the battery. For determining the discharge power capability, a maximum value of the battery current (I) is used in conjunction with a minimum value of the battery voltage. Equation 15 can be used to solve for (Iₘₐₓ) as shown in Equation 19.

$${I}_{max} ( {t}_{d} , {V}_{min} ) = \frac{( {V}_{oc} - {V}_{min} - {\hat{V}}_{2} ( 0 ) {e}^{- {t}_{d / ( {\hat{r}}_{2} \hat{c} )}} )}{[ {\hat{r}}_{1} + {\hat{r}}_{2} ( 1 - {e}^{- {t}_{d} / ( {\hat{r}}_{2} \hat{c} )} ) ]} \qquad Eq . 19$$

where: Vₘᵢₙ is a minimum operating voltage of the battery pack.

This current is then compared with a system discharge current limit Tₗᵢₘ_{_{—}}_{dch}. If Iₘₐₓ(t_{d}, Vₘᵢₙ)>Iₗᵢₘ_{_{—}}_{dch}, a second voltage value is calculated according to equation 20 as shown below:

$${\overline{V}}_{dch} = {V}_{oc} - {\hat{V}}_{2} ( 0 ) {e}^{- {t}_{d / ( {\hat{r}}_{2} \hat{c} )}} - {I}_{lim\_dch} * [ {\hat{r}}_{1} + {\hat{r}}_{2} ( 1 - {e}^{- {t}_{d} / ( {\hat{r}}_{2} \hat{c} )} ) ] \qquad Eq . 20$$

The discharge power capability (P_{cap}_{_{—}}_{dch}(t_{d})) for the battery as a function of the time (t_{d}) can be determined as shown in Equation 21.

$${P}_{cap\_dch} ( {t}_{d} ) = \{ \begin{matrix}\vert {I}_{max} \vert * {V}_{min} & if {I}_{max} \geq {I}_{lim\_dch} \\ \vert {I}_{lim\_dch} \vert * {\overline{V}}_{ch} & Otherwise\end{matrix} \qquad Eq . 21$$

Equations 15-21 calculate power capability using battery ECM parameters (e.g., r₁, r₂ and c) that are estimated by the EKF (Equations 7-10).

The signal characteristics of the measured battery power signals (e.g., battery current I, and terminal voltage Vₜ) affect the EKF estimations. The EKF estimations may “drift” or deviate from actual values under certain circumstances. For example, when the battery power levels are low (normally the situation when the current is small and current sensor measurement error may become significant as compared to higher current situations), the EKF may use a significantly biased sensor reading value as compared to the actual value, which may result in the EKF estimations deviating from actual values. Another example is when the measurement signals are stationary. In this case, the signal noise becomes significant when a derivative of the measurement signal is calculated. One further example is essentially related to the model itself. At times, the ECM does not accurately correlate to actual battery behavior. If the EKF is still attempting to estimate the model parameters using the actual battery measurement data, some of the EKF estimations may become out of range.

FIG. 4 illustrates a graph 410 of the measured battery current (I), and the estimated internal resistance of the battery over time. The internal resistance of the battery as estimated by the EKF is referenced by curve (r₁_{_{—}}_{EKF}). FIG. 4 depicts a drive cycle in which the vehicle is driving, or being propelled at least in part by the electric machines 18, 24 (shown in FIG. 1), between time T₀ and T₁. Generally, the current provided to the electric machines 18, 24 fluctuates when the vehicle is in motion due to various vehicle operating modes. At time T₁, the vehicle stops and idles until time T₂. Then at time T₂, the vehicle begins driving and is propelled at least in part by the electric machines 18, 24.

When the electric machines 18, 24 are operating to propel the vehicle, they may draw over one hundred amps of current, as generally referenced by numeral 412. When the vehicle is at idle, the electric machines 18, 24 may draw little or no current from the battery 16. Other vehicle systems may still be operating while the vehicle is at idle, (e.g., audio and thermal systems), therefore the electrical loads of such systems may still draw battery current, however it may be generally stable, as referenced by numeral 414. When the battery current is low and stable (e.g., at point 414) the input signals are insufficient for EKF estimations, and the EKF estimations (e.g., r₁) begin to deviate from nominal values, as illustrated at point 416. Once the vehicle begins moving again at time T₂, the battery current (I) will increase, and the EKF estimations will return to nominal values, as indicated by numeral 418. FIG. 4A is an enlarged view of a portion of the graph 410.

With reference to FIG. 5, a method for selectively updating battery ECM parameters based on signal characteristics is illustrated according to one or more embodiments and is generally referenced by numeral 510. The method 510 is implemented using software code contained within the BECM 14 according to one or more embodiments. In other embodiments, the method 510 is implemented in other vehicle controllers, or multiple vehicle controllers.

In operation 512, the BECM 14 initializes and sets a LOCK_{flag} equal to TRUE. The BECM 14 includes a plurality of flags, which are calibration values that are continuously updated. When the LOCK_{flag} is equal to TRUE, the BECM 14 bypasses presently determined EKF estimations, and references prior determined ECM parameters for calculating battery characteristics (e.g., P_{cap}, SOC, and battery state of health).

In operation 514, the BECM 14 receives input that is indicative of the battery terminal voltage (Vₜ) and the battery current (I). The input is provided by battery sensors according to one or more embodiments. The BECM 14 also receives present EKF estimations (e.g., r₁, r₂ and c) that are estimated by the EKF. The BECM 14 stores prior ECM parameters in its memory.

In operation 516 the BECM 14 determines battery control parameters, that correspond to upper and lower boundaries for various battery power signal characteristics. These boundaries include battery power boundaries (P_{HIGH} and P_{LOW}), where battery power (P) is the product of battery terminal voltage (Vᵢ) and battery current (I). The boundaries also include terminal voltage derivative, or rate of change boundaries ((dVₜ/dt)_{HIGH} and (dVₜ/dt)_{LOW}), battery current derivative, or rate of change boundaries ((dI/dt)_{HIGH} and (dI/dt)_{LOW}), and battery current boundaries (I_{HIGH} and I_{LOW}). In one or more embodiments, the BECM 14 determines the following values for the control parameters at operation 516: a power upper boundary (P_{HIGH}) between 200 W and 2.0 kW, a power lower boundary (P_{LOW}) between −100 kW and 0 kW, a voltage derivative upper boundary ((dVₜ/dt)_{HIGH}) of approximately 20 V/s, a voltage derivative lower boundary ((dVₜ/dt)_{LOW}) of approximately 10 V/s, a current derivative upper boundary ((dI/dt)_{HIGH}) of approximately 40 A/s, a current derivative lower boundary ((dI/dt)_{LOW}) of approximately 12 A/s, a current upper boundary (UGH) of approximately 5 A, and a current lower boundary (I_{LOW}) of approximately 1 A. Upper and lower boundaries are used rather than threshold values, to provide hysteresis and to avoid excessive switching between states. Although the boundaries are designated as “HIGH” or “LOW”; these designations are relative to EKF estimations and may not be considered “HIGH” or “LOW” in other contexts.

In operation 518, the BECM 14 analyzes the LOCK_{flag} to determine if it is TRUE or FALSE. If the determination at operation 518 is positive (e.g., LOCK_{flag} is TRUE), then the BECM 14 proceeds to operation 520, 522, 524, and 526 to evaluate the following four “UNLOCK” conditions, in which the battery power signal characteristics are compared to upper boundary control parameters:

$$1. {V}_{t} * I > {P}_{HIGH}$$

$$2. \vert \frac{d {V}_{t}}{d t} \vert > {( \frac{d {V}_{t}}{d t} )}_{HIGH}$$

$$3. \vert \frac{d I}{d t} \vert > {( \frac{d I}{d t} )}_{HIGH}$$

$$4. \vert I \vert > {I}_{HIGH}$$

If all of the above “UNLOCK” conditions are satisfied, then the BECM 14 will determine that the present battery input signals are sufficient for EKF estimations.

More specifically, the first UNLOCK condition is evaluated at operation 520. The battery power (Vₜ*I) is compared to the battery power upper boundary (P_{HIGH}), to determine if the battery power input is sufficient for EKF estimations. If the determination at operation 520 is positive, (e.g., Vₜ*I is greater than P_{HIGH}), then the BECM 14 proceeds to operation 522.

At operation 522, the second UNLOCK condition is evaluated. An absolute value of a derivative of the battery terminal voltage (|dVₜ/dt|) is compared to the battery terminal voltage derivative upper boundary (dVₜ/dt)_{HIGH}, to determine if the derivative of the battery terminal voltage is sufficient for EKF estimations. If the determination at operation 522 is positive, (e.g., |dVₜ/dt| is greater than (dVₜ/dt)_{HIGH}), then the BECM 14 proceeds to operation 524.

The third UNLOCK condition is evaluated at operation 524. An absolute value of a derivative of the battery current (|dI/dt|) is compared to the battery current derivative upper boundary (dI/dt)_{HIGH} to determine if the derivative of the battery current is sufficient for EKF estimations. If the determination at operation 524 is positive (e.g, (|dI/dt|) is greater than (dI/dt)_{HIGH}), then the BECM 14 proceeds to operation 526.

At operation 526, the fourth UNLOCK condition is evaluated. An absolute value of the battery current (I) is compared to the battery current upper boundary (I_{HIGH}), to determine if the battery is currently providing current that is sufficient for EKF estimations. If the determination at operation 526 is positive (e.g, I is greater than I_{HIGH}), then the BECM 14 proceeds to operation 528.

At operation 528, the BECM 14 sets the LOCK_{flag} equal to FALSE (UNLOCK), once it has determined that all of the battery power signal characteristics as analyzed in operations 520, 522, 524, and 526 are sufficient for EKF estimations.

If the determination at operation 518 is negative (e.g., LOCK_{flag} is FALSE), then the BECM 14 proceeds to operations 530, 532, 534, and 536, to evaluate the following four “LOCK” conditions, in which the battery power signal characteristics are compared to lower boundary control parameters:

$$1. {V}_{t} * I > {P}_{LOW}$$

$$2. \vert \frac{d {V}_{t}}{d t} \vert > {( \frac{d {V}_{t}}{d t} )}_{LOW}$$

$$3. \vert \frac{d I}{d t} \vert > {( \frac{d I}{d t} )}_{LOW}$$

$$4. \vert I \vert > {I}_{LOW}$$

If any of the above conditions are satisfied, then the BECM 14 will determine that the present battery input signals are insufficient for EKF estimations.

More specifically, the first LOCK condition is evaluated at operation 530. The battery power (Vₜ*I) is compared to the battery power lower boundary (P_{LOW}) to determine if the battery is currently providing power that is insufficient for EKF estimations. In one embodiment P_{LOW} is equal to 0 Watts. If the determination at operation 530 is negative (e.g, Vₜ*I is not less than P_{LOW}), then the BECM 14 proceeds to operation 532.

At operation 532, the second LOCK condition is evaluated. An absolute value of a derivative of the battery terminal voltage (|dVₜ/dt|) is compared to the battery terminal derivative lower boundary (dVₜ/dt)_{LOW}, to determine if the derivative of the battery voltage is insufficient for EKF estimations. If the determination at operation 532 is negative (e.g, (|dVₜ/dt|) is not less than (dVₜ/dt)_{LOW}), then the BECM 14 proceeds to operation 534.

The third LOCK condition is evaluated at operation 534. An absolute value of a derivative of the battery current (|dI/dt|) is compared to the battery current derivative lower boundary (dI/dt)_{LOW}, to determine if the derivative of the battery current is insufficient for EKF estimations. If the determination at operation 534 is negative (e.g, (|dI/dt|) is not less than (dI/dt)_{LOW}), then the BECM 14 proceeds to operation 536.

At operation 536, the fourth LOCK condition is evaluated. An absolute value of the battery current (I) is compared to the battery current lower boundary (I_{LOW}), to determine if the battery is currently providing current that is insufficient for EKF estimations.

If any of the determinations at operations 530, 532, 534, and 536 are positive, then the BECM 14 will determine that the present battery input signals are insufficient for EKF estimations, and proceed to operation 538. At operation 538, the BECM 14 sets the LOCK_{flag} equal to TRUE.

After operations 528 or 538, the BECM 14 proceeds to operation 540. If the determination at any of operations 520, 522, 524 or 526 is negative, the BECM 14 maintains the LOCK_{flag} setting of TRUE, and proceeds to operation 540. Additionally, if the determination at all of the operations 530, 532, 534 and 536 is negative, then the BECM 14 maintains the LOCK_{flag} setting of FALSE, and proceeds to operation 540.

In operation 540, the BECM 14 again analyzes the LOCK_{flag} to determine if it is TRUE or FALSE. If the determination at operation 540 is positive (e.g., LOCK_{flag} is TRUE), then the BECM 14 proceeds to operation 542 and bypasses the present EKF estimations that were received in operation 514, and references prior ECM parameters. Then at operation 544, the BECM 14 calculates battery characteristics (e.g., Pcap, and SOC) using the prior ECM parameters. If the determination at operation 540 is negative (e.g., LOCK_{flag} is FALSE), then the BECM 14 proceeds to operation 546 and updates the ECM parameters with the present EKF estimations that were received in operation 514. Then at operation 544, the BECM 14 calculates battery characteristics (e.g., Pcap, and SOC) based on the present EKF estimations. After operation 544, the BECM 14 returns to operation 514 for another iteration of the method 510.

FIGS. 4 and 4A illustrate the impact of the method 510. As stated above, the graph 410 includes the measured battery current (I), and the internal resistance of the battery as estimated by the EKF (r₁_{_{—}}_{EKF}). The graph 410 also includes a curve (r₁_{_{—}}_{ECM}) that represents the battery ECM parameters of the internal resistance of the battery as estimated by the EKF, and selectively updated by the method 510.

With reference to FIG. 4A, point 550 on curve I illustrates a point where the current is not changing significantly. Accordingly, at operation 534 of the method, the BECM 14 may determine that the absolute value of the derivative of the battery current (|dI/dt|) is less than the battery current derivative lower boundary (dI/dt)_{LOW}. The BECM 14 then proceeds to operation 538 and sets the LOCK_{flag} equal to TRUE. Then at operation 542 the BECM 14 bypasses present EKF estimations (e.g., point 552 on r₁_{_{—}}_{EKF}, and references prior ECM parameters, as illustrated by point 554 on r₁_{_{—}}_{ECM}.

Additionally, point 560 on curve I, illustrates a point where the current is changing, however the absolute value of the current is low. Accordingly, at operation 536 of the method, the BECM 14 may determine that the absolute value of the battery current (|I|) is less than the battery current lower boundary I_{LOW}. The BECM 14 then proceeds to operation 538 and sets the LOCK_{flag} equal to true. Then at operation 542 the BECM 14 bypasses present EKF estimations (e.g., point 562 on r₁_{_{—}}_{EKF}, and references prior ECM parameters, as illustrated by point 564 on r₁_{_{—}}_{ECM}.

However, point 570 on curve I illustrates a point where the current is changing significantly, and the current is not low. Accordingly, at operation 524 of the method, the BECM 14 may determine that the absolute value of the rate of change of the battery current (|dI/dt|) is greater than the battery current rate of change upper boundary (dI/dt)_{HIGH}. Then the BECM 14 proceeds to operation 526. At operation 526, the BECM 14 determines that the absolute value of the battery current (|I|) is greater than the battery current upper boundary I_{HIGH}. The BECM 14 then proceeds to operation 528 and sets the LOCK_{flag} equal to FALSE. Then at operation 546 the BECM 14 updates the ECM parameters with the presently estimated EKF estimations, as illustrated by point 572 on r₁_{_{—}}_{EKF} corresponding to point 574 on r₁_{_{—}}_{ECM}.

As such, the vehicle system 10 provides advantages over existing methods by bypassing presently estimated EKF estimations, and referencing prior ECM parameters, when the signal characteristics of the input (e.g., Vₜ and I) are, for example, low or stationary, and thus insufficient for EKF estimations. Such selective updating of battery ECM parameters results in a more accurate estimation of battery characteristics (e.g., P_{cap}, and SOC) throughout the battery operating range and at different vehicle conditions.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A vehicle comprising:
an electric machine configured to provide drive torque;
a battery for supplying power to the electric machine; and
a controller configured to:
estimate present battery parameters based on input indicative of the power supplied by the battery; and
generate output indicative of battery power capability based on the input and prior battery parameters in response to a rate of change of a component of the power being less than a lower boundary.

2. The vehicle of claim 1 wherein the controller is further configured to:
generate battery estimations using a predictive filter;
update the present battery parameters with the battery estimations in response to the rate of change of the component of the power being greater than an upper boundary; and
bypass the battery estimations and reference the prior battery parameters in response to the rate of change of the component of the power being less than a lower boundary, wherein the upper boundary is greater than the lower boundary.

3. The vehicle of claim 1 wherein the controller is further configured to:
receive input indicative of a battery voltage and a battery current; and
generate the output indicative of the battery power capability based on the input and the prior battery parameters in response to a product of the battery voltage and the battery current being less than a power lower boundary.

4. The vehicle of claim 1 wherein the controller is further configured to:
receive input indicative of a battery voltage; and
generate the output indicative of the battery power capability based on the input and the prior battery parameters in response to an absolute value of a rate of change of the battery voltage being less than a battery voltage derivative lower boundary.

5. The vehicle of claim 1 wherein the controller is further configured to:
receive input indicative of a battery current; and
generate the output indicative of the battery power capability based on the input and the prior battery parameters in response to an absolute value of a rate of change of the battery current being less than a battery current derivative lower boundary.

6. The vehicle of claim 1 wherein the controller is further configured to:
receive input indicative of a battery current; and
generate the output indicative of the battery power capability based on the input and the prior battery parameters in response to an absolute value of the battery current being less than a current lower boundary.

7. A vehicle system comprising:
a battery for supplying power; and
a controller configured to:
receive a first input indicative of first battery power;
receive a second input indicative of second battery power; and
generate output indicative of battery power capability based on the second input and prior battery parameters based on the first input, in response to a rate of change of a component of the second input being less than a lower boundary.

8. The vehicle system of claim 7 wherein the second input includes a second voltage and a second current, and wherein the controller is further configured to:
generate the output indicative of battery power capability based on the second input and present battery parameters based on the second input, in response to a product of the second voltage and the second current being greater than a power upper boundary.

9. The vehicle system of claim 8 wherein the controller is further configured to:
generate the output indicative of battery power capability based on the second input and the present battery parameters in response to an absolute value of a rate of change of the second voltage being greater than a voltage derivative upper boundary.

10. The vehicle system of claim 9 wherein the controller is further configured to:
generate the output indicative of battery power capability based on the second input and the present battery parameters in response to an absolute value of a rate of change of the second current being greater than a current derivative upper boundary.

11. The vehicle system of claim 10 wherein the controller is further configured to:
generate the output indicative of battery power capability based on the second input and the present battery parameters in response to an absolute value of the second current being greater than a current upper boundary; and
generate the output indicative of battery power capability based on the second input and the prior battery parameters in response to an absolute value of the second current being less than a current lower boundary, wherein the current upper boundary is greater than the current lower boundary.

12. The vehicle system of claim 8 wherein the controller is further configured to:
generate the output indicative of the battery power capability based on the second input and the prior battery parameters in response to a product of the second voltage and the second current being less than a power lower boundary.

13. The vehicle system of claim 8 wherein the controller is further configured to:
generate the output indicative of the battery power capability based on the second input and the prior battery parameters in response to an absolute value of a rate of change of the second voltage being less than a voltage derivative lower boundary.

14. The vehicle system of claim 8 wherein the controller is further configured to:
generate the output indicative of the battery power capability based on the second input and the prior battery parameters in response to an absolute value of a rate of change of the second current being less than a current derivative lower boundary.

15. A method for controlling a hybrid vehicle, the method comprising:
receiving a first input indicative of first battery power;
receiving a second input indicative of second battery power; and
calculating a battery power capability based on the second input and an estimate of first battery ECM parameters based on the first input, in response to a rate of change of a component of the second input being less than a lower boundary.

16. The method of claim 15 wherein the second input includes a second voltage and a second current, the method further comprising:
calculating the battery power capability based on the second input and second battery ECM parameters based on the second input, in response a product of the second voltage and the second current being greater than a power upper boundary.

17. The method of claim 16 further comprising:
calculating the battery power capability based on the second input and the first battery ECM parameters in response to a product of the second voltage and the second current being less than a power lower boundary, wherein the power lower boundary is less than the power upper boundary.

18. The method of claim 15 wherein the second input includes a second voltage and a second current, the method further comprising:
calculating the battery power capability based on the second input and the first battery ECM parameters in response to an absolute value of a rate of change of the second voltage being less than a battery voltage derivative lower boundary.

19. The method of claim 15 wherein the second input includes a second voltage and a second current, the method further comprising:
calculating the battery power capability based on the second input and the first battery ECM parameters in response to an absolute value of a rate of change of the second current being less than a battery current derivative lower boundary.

20. The method of claim 15 wherein the second input includes a second voltage and a second current, the method further comprising:
calculating the battery power capability based on the second input and the first battery ECM parameters in response to an absolute value of the second current being less than a current lower boundary.
